(19) United States
(12) Patent Application Publication
(10) Pub. No.: US 2020/0075507 A1
(43) Pub. Date: Mar. 5, 2020

(54) SEMICONDUCTOR DEVICE AND METHOD FOR PREPARING THE SAME

(71) Applicant: NANYA TECHNOLOGY CORPORATION, New Taipei City (TW)

(72) Inventor: TING-CIH KANG, NEW TAIPEI CITY (TW)

(21) Appl. No.: 16/117,581

(22) Filed: Aug. 30, 2018

(51) Int. Cl. H01L 23/58; H01L 23/00; H01L 23/552

(52) U.S. Cl. CPC H01L 23/585; H01L 23/552; H01L 23/564; H01L 23/562

(57) ABSTRACT

The present disclosure provides a semiconductor device and a method for preparing the same. The semiconductor device includes at least one chip and a seal ring. The chip is surrounded by the seal ring. The seal ring includes at least one first section and at least one second section. The first section includes an undulating structure.

### TECHNICAL FIELD

The present disclosure relates to a semiconductor device including a seal ring, and more particularly to semiconductor device including an undulating seal ring.

### DISCUSSION OF THE BACKGROUND

With the development of electronic technology, semiconductor components are getting smaller, and devices are providing more powerful functions with more integrated circuits. Due to the decreasing size of semiconductor components, the wafer-level chip scale packages (WLCSP) are widely used in manufacturing.

The seal ring in an integrated circuit is used to protect the integrated circuit from cracking during cutting (wafer cutting) and to prevent moisture from entering the integrated circuit. However, the seal ring can introduce noise from external radio frequency (RF) signals through the metal path of the seal ring into the integrated circuit, thereby seriously affecting the performance of the device. Moreover, the seal ring generates a noise path, so that noise can be transmitted to other areas of the integrated circuit. In addition, the mutual inductance generated by the induced current along the seal ring also generates noise.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a semiconductor device including at least one chip and a seal ring. The seal ring is configured to surround the chip and comprises at least one first section and at least one second section.

In some embodiments, the second section comprises an undulating structure.

In some embodiments, the second section comprises a linear structure.

In some embodiments, the seal ring is a closed loop.

In some embodiments, the seal ring comprises at least one first layer.

In some embodiments, the seal ring further comprises at least one second layer.

In some embodiments, the first layer comprises a via.

In some embodiments, the material of the second layer is copper.

Another aspect of the present disclosure provides a semiconductor device comprising: a substrate having a pattern thereon, wherein the pattern includes an inner contour and an outer contour; a first via layer disposed on the pattern of the substrate base; a first metal layer disposed on the first via layer; a second via layer disposed on the first metal layer; a second metal layer disposed on the second via layer; a third via layer disposed on the second metal layer; a third metal layer disposed on the third via layer; a passivation oxide layer disposed covering the third metal layer; and a passivation nitride layer disposed covering the passivation oxide layer, wherein the pattern comprises at least one first section and at least one second section and the first section includes an undulating pattern.

In some embodiments, the second section comprises an undulating structure.

In some embodiments, the second section comprises a linear structure.

In some embodiments, the seal ring is a closed loop.

Another aspect of the present disclosure provides a method for preparing a semiconductor device, the method comprising: providing a substrate having a pattern thereon, wherein the pattern includes an inner contour and an outer contour; forming a first via layer on the substrate base on the pattern; forming a first metal layer on the first via layer; forming a second via layer on the first metal layer; forming a second metal layer on the second via layer; forming a third via layer on the second metal layer; forming a third metal layer on the third via layer; forming a passivation oxide layer covering the third metal layer; and forming a passivation nitride layer covering the passivation oxide layer, wherein the pattern comprises at least one first section and at least one second section and the first section includes an undulating pattern.

In some embodiments, the step of forming a first via layer on the substrate further comprises forming at least one via in the first via layer.

In some embodiments, the material of the first metal layer is copper.

In some embodiments, the step of forming a second via layer on the substrate further comprises forming at least one via in the second via layer.

In some embodiments, the material of the second metal layer is the same as the material of the first metal layer.

In some embodiments, the material of the second metal layer is different from that of the first metal layer.

In some embodiments, the quantity of vias in the second via layer is the same as the quantity of vias in the first via layer.

In some embodiments, the quantity of vias in the second via layer is different from the quantity of vias in the first via layer.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should be understood to be connected to the figures' reference numbers, which refer to similar elements throughout the description.

FIG. 1 is a schematic diagram showing a comparative semiconductor device.

FIG. 2 is a schematic diagram showing a semiconductor device in accordance with some embodiments of the present disclosure.

FIG. 3 is a schematic diagram showing another semiconductor device in accordance with some embodiments of the present disclosure.

FIG. 4 is a schematic diagram showing another semiconductor device derived from the semiconductor device shown in FIG. 3 in accordance with some embodiments of the present disclosure.

FIG. 5 is a schematic diagram showing another semiconductor device derived from the semiconductor device shown in FIG. 3 in accordance with some embodiments of the present disclosure.

FIG. 6 is a schematic diagram showing yet another semiconductor device derived from the semiconductor device shown in FIG. 3 in accordance with some embodiments of the present disclosure.

FIG. 7 is a schematic diagram showing still another semiconductor device derived from the semiconductor device shown in FIG. 3 in accordance with some embodiments of the present disclosure.

FIG. 8A is a schematic diagram illustrating a substrate in accordance with some embodiments of the present disclosure.

FIG. 8B is a schematic diagram illustrating a first via layer disposed on the substrate in accordance with some embodiments of the present disclosure.

FIG. 8C is a schematic diagram illustrating a first metal layer disposed on the first via layer in accordance with some embodiments of the present disclosure.

FIG. 8D is a schematic diagram illustrating a second via layer disposed on the first metal layer in accordance with some embodiments of the present disclosure.

FIG. 8E is a schematic diagram illustrating a second metal layer disposed on the second via layer in accordance with some embodiments of the present disclosure.

FIG. 8F is a schematic diagram illustrating a third via layer disposed on the second metal layer in accordance with some embodiments of the present disclosure.

FIG. 8G is a schematic diagram illustrating a third metal layer disposed on the third via layer in accordance with some embodiments of the present disclosure.

FIG. 8H is a schematic diagram illustrating a passivation oxide layer disposed covering the third metal layer in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

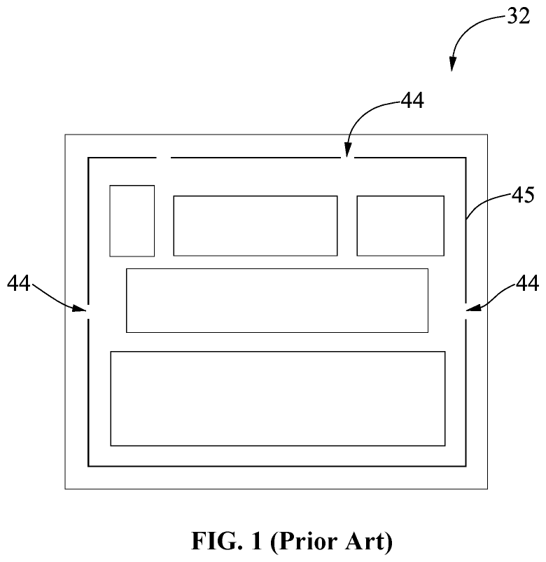

FIG. 1 is a schematic diagram showing a comparative semiconductor device 32 by reference to U.S. Pat. No. 6,492,716. Referring to FIG. 1, a broken seal ring 45 has a slit 44 at a specific position to reduce interference caused by external noise. However, moisture may permeate through the unsealed slit 44, thereby causing problems such as reduced reliability and early breakdown. Moreover, the structure of the unsealed ring is not suitable for an extra low-k device.

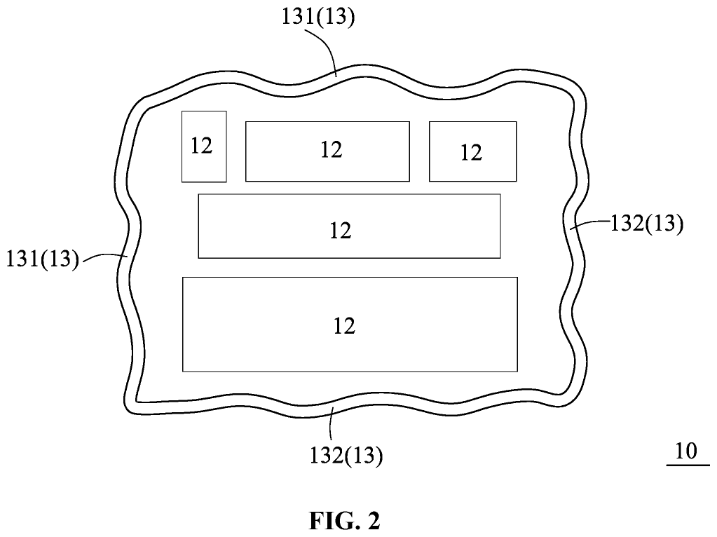

FIG. 2 is a schematic top view of a semiconductor device 10 in accordance with some embodiments of the present disclosure. Referring to FIG. 2, the semiconductor device 10 includes at least one chip 12 (five chips are used for example in FIG. 2) and a seal ring 13. The chips 12 are surrounded by a seal ring 13 and the seal ring 13 includes at least one first section 131 and at least one second section 132. Both the first section 131 and the second section 132 have an undulating structure. In other words, the seal ring 13 is entirely undulating and forms a closed loop. In this way, since the undulating seal ring 13 has destructive interference (the amplitude of the two waves is nearly or exactly the same, and since the amplitude of the composite wave approaches zero when the reverse interference is performed), only a very small portion of the noise can pass through the seal ring 13. Therefore, the seal ring 13 enables the semiconductor device 10 to reduce coupling noise compared to the comparative semiconductor device 32 shown FIG. 1. Moreover, the seal ring 13 surrounds the periphery of the chips 12 in a state like a solid wall, so that the chips 12 can be protected from moisture permeation and ionic contamination.

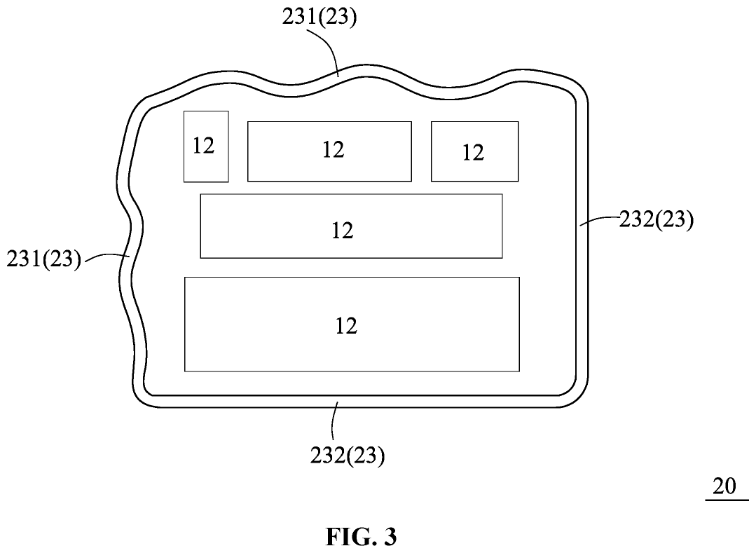

FIG. 3 is a schematic top view showing another semiconductor device 20 in accordance with some embodiments of the present disclosure. Referring to FIG. 3, the difference between the semiconductor device 20 and the semiconductor device 10 (as shown in FIG. 2) is that the second section 232 of the seal ring 23 of the semiconductor device 20 is a linear structure (in contrast, the second section 132 of the seal ring 13 of the semiconductor device 10 is an undulating structure). Like the first section 131 of the seal ring 13 of the semiconductor device 10, the first section 231 of the seal ring 23 is an undulating structure. Since the seal ring 23 includes an undulating structure (i.e., the first section 231), the seal ring 23 can reduce internal and external noise interference of the semiconductor device 20 and prevent moisture from penetrating into the interior of the semiconductor device 20 (because the seal ring 23 is a closed loop).

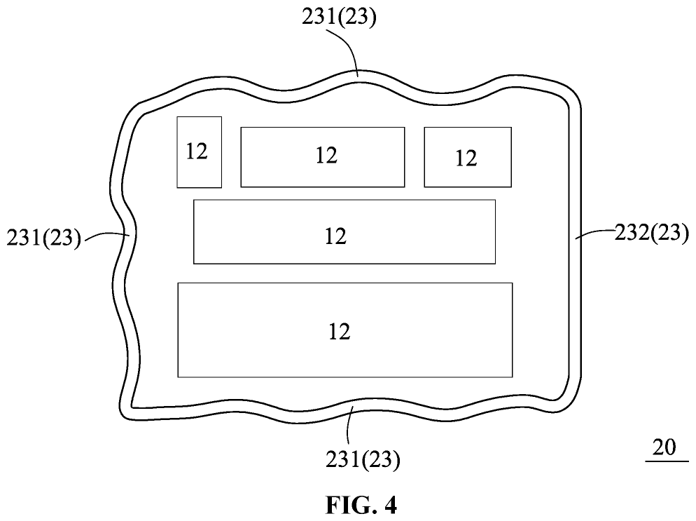

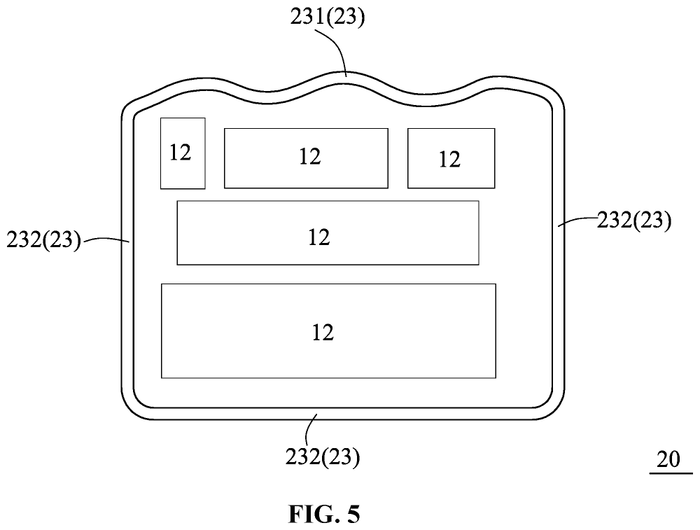

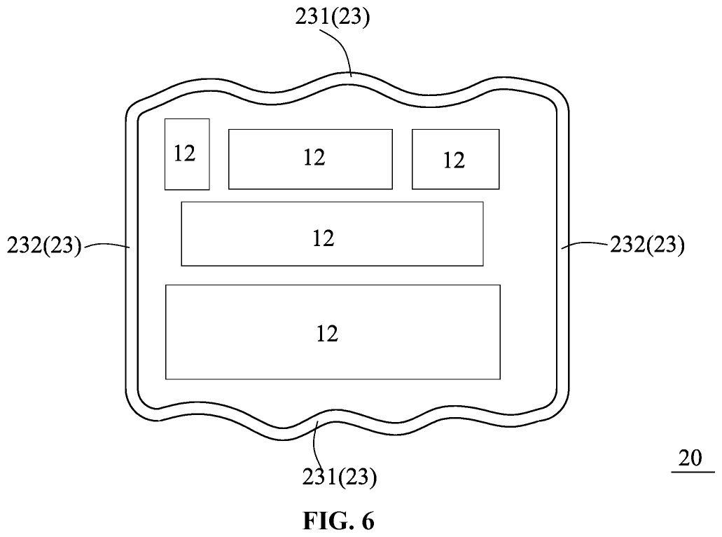

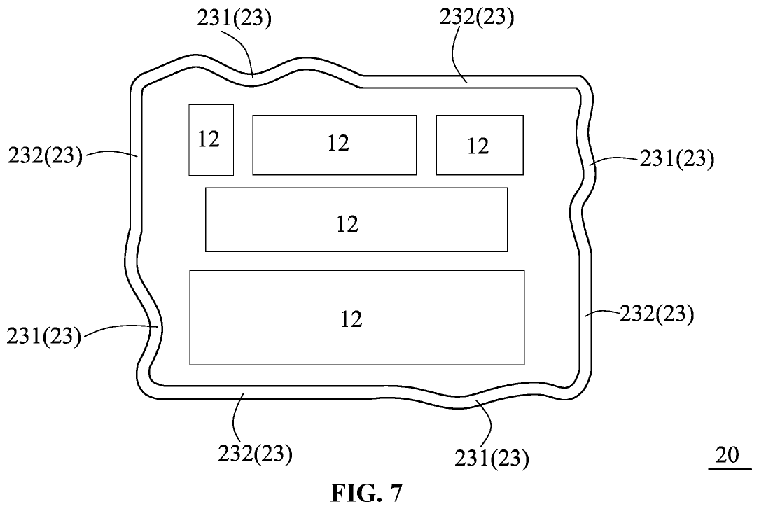

FIG. 4 to FIG. 7 are schematic diagrams showing various semiconductor devices derived from semiconductor device shown in FIG. 3 in accordance with some embodiments of the present disclosure. As shown in FIG. 4, in some embodiments, the second section 232 includes only one side of the seal rings 23, and the first section 231 includes the other three directions (the other three sides) of the seal ring 23. Therefore, a seal ring 23 with such structure has more undulations compared to the seal ring 23 shown in FIG. 3. In contrast, in FIG. 5, in some embodiments, the first section 231 includes only one side of the seal rings 23, and the second section 232 includes the other three sides of the seal ring 23 (the other three directions), and the seal ring 23 with such structure has fewer undulations compared to the seal ring 23 shown in FIG. 3. Moreover, as shown in FIG. 6, in some embodiments, the seal ring 23 has two first sections 231 which are parallel to each other and two second sections 232 which are parallel to each other, so that the surrounding range of the undulating structure of the seal ring 23 is the same as the surrounding range of the linear structure. In addition, in FIG. 7, in some embodiments, the four directions (four sides) of the seal ring 23 have both the first section 231 and the second section 232, such that the undulating structure and the linear structure of the seal ring 23 are evenly distributed. Although the seal rings 23 described above includes a variety of forms, the seal ring 23 still include at least one undulating structure and thus can reduce the internal and external noise interference and prevent moisture from penetrating into the interior.

Additionally, in some embodiments, the material of the seal ring 13 includes, but is not limited to, a conductive material or a metallic material such as copper or aluminum. In some embodiments, the seal ring 13 has a plurality of layers, such as a metal layer and a via layer. The metal layer and the via layer can comprise any suitable material and can be formed by or fabricated by any suitable method or process in the art. For example, the metal layer may comprise aluminum, copper, tin, nickel, gold, silver or other suitable material and may be deposited by electroplating, physical vapor deposition, sputtering, or any suitable process, and etched through a layer body. In some embodiments, the via layer comprises copper, copper alloy, tungsten, gold, aluminum, or other suitable material. The via layer can be formed, for example, by physical vapor deposition, chemical vapor deposition, or chemical mechanical polishing.

In summary, using an undulating seal ring, although the seal ring 23 may include only one undulating structure, the seal ring can still reduce the internal and external noise interference and prevent moisture from penetrating into the interior.

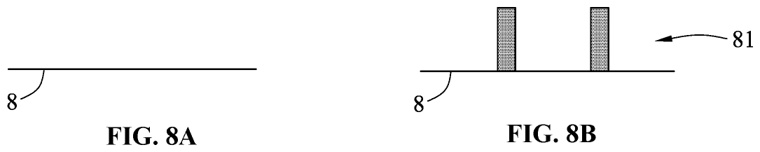

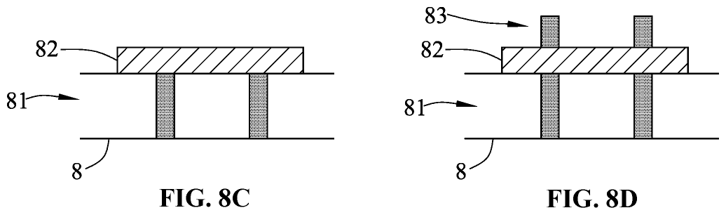

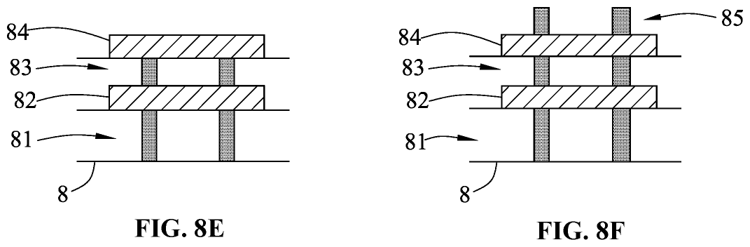

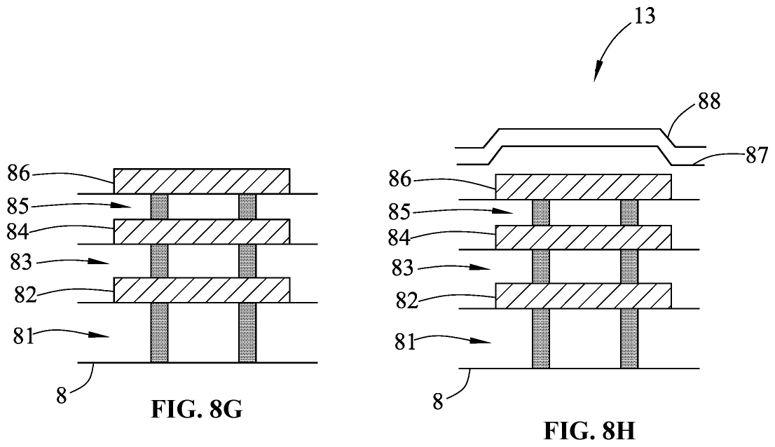

FIG. 8A to FIG. 8H illustrate a process for preparing a seal ring 13 in accordance with some embodiments of the present disclosure. First, referring to FIG. 8A, in some embodiments, a P-type substrate 8 is provided as a substrate. In some embodiments, the substrate 8 comprise an N-type substrate.

Referring to FIG. 8B, in some embodiments, a first via layer 81 is disposed on the P-type substrate 8 wherein at least one via is formed therein. The first via layer 81 can be formed or fabricated by any suitable method or process in the art. For example, a poly layer body is deposited and a via is formed by an etching process and then depositing a suitable conductive material such as copper.

Next, referring to FIG. 8C, in some embodiments, a first metal layer 82 is disposed on the first via layer 81.

Next, referring to FIG. 8D, in some embodiments, a second via layer 83 is disposed on the first metal layer 82. The second via layer 83 includes at least one via therein. In some embodiments, the quantity of vias included in the via layer 83 is equal to the quantity of vias included in the via layer 81. In some embodiments, the quantity of vias included in the via layer 83 is not equal to the quantity of vias included in the via layer 81. The method and process of forming and fabricating the via layer 83 is similar to those of the via layer 81.

Next, referring to FIG. 8E, in some embodiments, a second metal layer 84 is disposed on the second via layer 83. In some embodiments, the material of the second metal layer 84 is the same as the material of the first metal layer 82. In some embodiments, the material of the second metal layer 84 is different from the material of the first metal layer 82. The method and process of forming and fabricating the second metal layer 84 are similar to those of the first metal layer 82.

Next, referring to FIG. 8F, in some embodiments, a third via layer 85 is disposed on the second metal layer 84. The third via layer 85 includes at least one via therein. In some embodiments, the quantity of vias in the third via layer 85 is equal to the quantity of vias in the second via layer 83. In some embodiments, the quantity of vias in the third via layer 85 is not equal to the quantity of vias in the second via layer 83. The method and process of forming and fabricating the third via layer 85 are similar to those of the second via layer 83.

Next, referring to FIG. 8G, a third metal layer 86 is disposed on the third via layer 85. In some embodiments, the material of the third metal layer 86 is the same as that of the second metal layer 84. In some embodiments, the material of the third metal layer 86 is different from that of second metal layer 84. The method and process of forming and fabricating the third metal layer 86 are similar to those of the second metal layer 84.

Next, referring to FIG. 8H, FIG. 8H shows the passivation oxidation. A passivation layer 87 and a passivation nitride layer 88 are disposed over the third metal layer 86. It should be noted that the passivation nitride layer 88 is disposed over the passivation oxide layer 87 in such a way that the cross-sectional structure of the seal ring 13 of the present disclosure is as shown in FIG. 8H.

The material of the first metal layer 82, the second metal layer 84, and the third metal layer 86 is, for example, copper, aluminum, or other suitable material. Moreover, in some embodiments, a passivation oxide layer 87 and a passivation nitride layer 88 can be formed in back-end processes. In summary, the semiconductor device of the present disclosure and the seal ring used in the semiconductor device circuit can reduce coupling noise and protect the chip from moisture penetration and ionic contamination.

The method illustrated above is merely an example and is not intended to limit the present disclosure beyond what is explicitly recited in the claims. Additional operations can be provided before, during, and after the method, and some operations described can be replaced, eliminated, or moved around for additional embodiments of the method.

One aspect of the present disclosure provides a semiconductor device including at least one chip and a seal ring. The seal ring is configured to surround the chip, and comprises at least one first section and at least one second section.

Another aspect of the present disclosure provides a semiconductor device comprising: a substrate having a pattern thereon, wherein the pattern includes an inner contour and an outer contour; a first via layer disposed on the substrate base on the pattern; a first metal layer disposed on the first via layer; a second via layer disposed on the first metal layer; a second metal layer disposed on the second via layer; a third via layer disposed on the second metal layer; a third metal layer disposed on the third via layer; a passivation oxide layer disposed covering the third metal layer; and a passivation nitride layer disposed covering the passivation oxide layer, wherein the pattern comprises at least one first section and at least one second section and the first section includes an undulating pattern.

Another aspect of the present disclosure provides a method for preparing a semiconductor device comprising: providing a substrate having a pattern thereon, wherein the pattern includes an inner contour and an outer contour; forming, a first via layer on the substrate base on the pattern; forming a first metal layer on the first via layer; forming a second via layer on the first metal layer; forming a second metal layer on the second via layer; forming third via layer on the second metal layer; forming a third metal layer on the third via layer; forming a passivation oxide layer covering the third metal layer; and forming a passivation nitride layer covering the passivation oxide layer, wherein the pattern comprises at least one first section and at least one second section and the first section includes an undulating pattern.

The scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor device comprising:
at least one chip; and
a seal ring configured to surround the chip and comprising a plurality of adjacent first sections and a plurality of adjacent second sections;
wherein the plurality of adjacent first sections and the plurality of adjacent second sections form a closed loop; and
wherein the plurality of adjacent first sections are undulating structures.

2. The semiconductor device of claim 1, wherein the plurality of adjacent second sections comprise an undulating structure.

3. The semiconductor device of claim 1, wherein the plurality of adjacent second sections comprise a linear structure.

4. (canceled)

5. The semiconductor device of claim 1, wherein the seal ring comprises at least one first layer.

6. The semiconductor device of claim 5, wherein the seal ring further comprises at least one second layer.

7. The semiconductor device of claim 5, wherein the first layer comprises a via.

8. The semiconductor device of claim 6, wherein a material of the second layer comprises copper.

9. A semiconductor device comprising:
a substrate having a pattern thereon, wherein the pattern includes an inner contour and an outer contour;
a first via layer disposed on the substrate base on the pattern;
a first metal layer disposed on the first via layer;
a second via layer disposed on the first metal layer;
a second metal layer disposed on the second via layer;
a third via layer disposed on the second metal layer;
a third metal layer disposed on the third via layer;
a passivation oxide layer disposed covering the third metal layer; and
a passivation nitride layer disposed covering the passivation oxide layer;
wherein the pattern comprises a plurality of first sections and a plurality of second sections, the plurality of first sections and the plurality of second sections form a closed loop, and the plurality of first sections are undulating patterns.

10. The semiconductor device of claim 9, wherein the plurality of second sections are undulating structures.

11. The semiconductor device of claim 9, wherein the plurality of second sections comprise a linear structure.

12. (canceled)

13. A method for preparing a semiconductor device, the method comprising:
providing a substrate having a pattern thereon, wherein the pattern includes an inner contour and an outer contour;
forming a first via layer on the substrate base on the pattern;
forming a first metal layer on the first via layer;
forming a second via layer on the first metal layer;
forming a second metal layer on the second via layer;
forming third via layer on the second metal layer;
forming a third metal layer on the third via layer;
forming a passivation oxide layer covering the third metal layer; and
forming a passivation nitride layer covering the passivation oxide layer;
wherein the pattern comprises a plurality of first sections and a plurality of second sections, the plurality of first sections and the plurality of second sections form a closed loop, and the plurality of first sections are undulating patterns.

14. The method of claim 13, wherein the step of forming a first via layer on the substrate further comprises forming at least one via in the first via layer.

15. The method of claim 13, wherein a material of the first metal layer is copper.

16. The method of claim 13, wherein the step of forming a second via layer on the substrate further comprises forming at least one via in the second via layer.

17. The method of claim 13, wherein a material of the second metal layer is the same as the material of the first metal layer.

18. The method of claim 13, wherein the material of the second metal layer is different from the material of the first metal layer.

19. The method of claim 16, wherein a quantity of vias in the second via layer is the same as a quantity of vias in the first via layer.

20. The method of claim 16, wherein a quantity of vias in the second via layer is different from a quantity of vias in the first via layer.
